(19) United States
(12) Patent Application Publication
(10) Pub. No.: US 2010/0159691 A1
(43) Pub. Date: Jun. 24, 2010

(54) PHOTOSENSITIVE RESIN COMPOSITION AND LAMINATE

(76) Inventor: Yamato Tsutsui, Tokyo (JP)

Correspondence Address: FINNEGAN, HENDERSON, FARABOW, GARRETT & DUNNER;LLP, 901 NEW YORK AVENUE, NW, WASHINGTON, DC, 20001-4413, US

(21) Appl. No.: 12/309,819

(22) PCT Filed: Jul. 27, 2007
(86) PCT No.: PCT/JP2007/064803

§ 371 Date: Jan. 30, 2009

(30) Foreign Application Priority Data
Aug. 3, 2006 (JP) 2006-211933

(51) Int. Cl. H01L 21/60; H01B 13/00; B05D 5/12; G03F 7/20; G03C 1/00; H01L 21/027; B24C 1/00

(52) U.S. Cl. 438/613; 216/13; 427/117; 430/271.1; 430/285.1; 430/286.1; 430/325; 438/758; 451/38; 257/E21.506; 257/E21.023

(57) ABSTRACT

Disclosed is a photosensitive resin composition showing excellent contrast performance after exposure to light. Also disclosed is a photosensitive resin laminate using the composition. The photosensitive resin composition comprises (a) 20 to 90% by mass of a binder having a carboxyl group, (b) 5 to 75% by mass of an addition-polymerizable monomer having at least one ethylenically unsaturated terminal group, (c) 0.01 to 30% by mass of a photopolymerization initiator, and (d) 0.01 to 10% by mass of a leuco dye, wherein a specific binder is contained as the binder (a) and a specific monomer is contained as the addition-polymerizable monomer (b).

### TECHNICAL FIELD

The present invention relates to a photosensitive resin composition which can be developed with an alkaline aqueous solution, a photosensitive resin laminate comprising the photosensitive resin composition laminated on a support, a method for forming a resist pattern on a substrate using the photosensitive resin laminate, and a use of the resist pattern. More particularly, it relates to a photosensitive resin composition which forms a resist pattern suitable as a protective masking member in production of printed wiring board, production of flexible printed wiring board, production of lead frame for mounting IC chip (hereinafter referred to as “lead frame”, precision working of metal foil such as production of metal mask, production of semiconductor package such as BGA (ball grid array) or CSP (chip size package), production of tape substrate such as TAB (TAPE Automated Bonding) or COF (Chip On Film: a filmy fine wiring board on which semiconductor IC is mounted), production of semiconductor bump, production of members such as ITO electrode or address electrode in the field of flat panel display and electromagnetic wave shield, and working of base by sandblasting method.

### BACKGROUND ART

Hitherto, printed wiring boards have been produced by photolithographic process. The photolithographic process is a process of forming a conductor pattern on a substrate which comprises coating a photosensitive resin composition on a substrate, subjecting the coat to pattern exposure to polymerize and harden the exposed portion of the photosensitive resin composition, removing the undeveloped portions with a developing solution to form a resist pattern on the substrate, followed by carrying out etching or plating treatment to form a conductor pattern, and then peeling and removing the resist pattern from the substrate to form a conductor pattern on the substrate.

For coating the photosensitive resin composition on the substrate in the above photolithographic process, there is used either a method of coating a solution of the photosensitive resin composition on a substrate and drying the coat or a method of laminating on the substrate a photosensitive resin laminate (hereinafter sometimes referred to as “dry film resist”) prepared by laminating a support, a layer comprising a photosensitive resin composition (hereinafter referred to as “photosensitive resin layer”) and, if necessary, a protective layer in succession. In many cases, the dry film resist is used in production of printed wiring boards.

The method of producing printed wiring boards using the dry film resist will be briefly explained below.

First, when the dry film resist includes a protective layer such as polyethylene film, the protective film is peeled off from the photosensitive resin layer. Then, the photosensitive resin layer and support are laminated on a substrate, e.g., a copper-clad laminate plate, using a laminator, so that the substrate, the photosensitive resin layer and the support are laminated in succession with the support being positioned uppermost. Then, the photosensitive resin layer is exposed to ultraviolet rays including i-line (365 nm) emitted from an ultra-high pressure mercury lamp through a photomask having a wiring pattern to polymerize and harden the exposed portions. Then, the support, e.g., a film comprising polyethylene terephthalate, is peeled off. Subsequently, the unexposed portions of the photosensitive resin layer are removed by dissolution or dispersion with a developing solution, namely, an aqueous solution having weak alkalinity to form a resist pattern on the substrate. Then, a known etching treatment or pattern plating treatment is carried out using the thus formed resist pattern as a protective mask. Finally, the resist pattern is peeled off from the substrate to produce a substrate having conductor pattern, namely, a printed wiring board.

In recent printed wiring boards, intervals between conductor patterns become minute, and thus the dry film resists are demanded to have high resolution and high adhesion properties. On the other hand, the kind of exposing method is diversified according to use, and recently, use of a maskless exposing method which is performed by direct drawing with laser and requires no photomask expands rapidly. As light sources of maskless exposure, in many cases, light of 350-410 nm in wavelength, especially, i-line or h-line (405 nm) is used. Therefore, it is important that there can be formed resist patterns of high resolution for light sources of these wavelength regions.

Furthermore, judgment by defect tester after exposure is generally conducted by discrimination between unexposed portion and exposed portion. The photosensitive resin layer of dry film resist contains a dye which forms color upon exposure. The contrast between unexposed portion and exposed portion is given by the color formation of the dye. For improving productivity, it is required that the photosensitive resin layer has good contrast just after exposure.

Patent Document 1 discloses a photosensitive resin composition comprising a tetrapolymer of methyl methacrylate/2-ethylhexyl acrylate/benzyl methacrylate/methacrylic acid and polyethylene glycol diacrylate (MW=742), and it refers to developing time, resolution, tenting film strength, and peeling time, but the contrast just after exposure is not fully satisfied.

Patent Document 2 discloses a photosensitive resin composition comprising a terpolymer of methyl methacrylate/methacrylic acid/styrene and (meth)acrylate comprising pentaerythritol to which a polyalkylene oxide group is added, but the contrast just after exposure is not fully satisfied.

Patent Document 3 discloses a photosensitive resin composition comprising a terpolymer of methacrylic acid/benzyl methacrylate/styrene and trimethylolpropane triacrylate, but the contrast just after exposure is not fully satisfied.

Patent Document 1: JP-A-63-147159

Patent Document 2: JP-A-2002-40646

Patent Document 3: JP-A-11-231535

### DISCLOSURE OF INVENTION

### Problem to be Solved by the Invention

The object of the present invention is to solve the above problems and to provide a photosensitive resin composition excellent in contrast performance just after exposure to light and a photosensitive resin laminate using the composition.

### Means for Solving the Problem

The above object can be attained by the following construction of the present invention.

(1) A photosensitive resin composition which comprises (a) 20-90% by mass of a carboxyl group-containing binder, (b) 5-75% by mass of an addition-polymerizable monomer having at least one ethylenically unsaturated terminal group, (c) 0.01-30% by mass of a photopolymerization initiator, and (d) 0.01-10% by mass of a leuco dye, wherein (a) the carboxyl group-containing binder has a weight-average molecular weight of 5,000-500,000 and contains a copolymer obtained by copolymerizing at least a monomer represented by the following formula (I) in an amount of 10-40% by mass, a monomer represented by the following formula (II) in an amount of 10-80% by mass and a monomer represented by the following formula (III) in an amount of 10-80% by mass, and (b) the addition-polymerizable monomer having at least one ethylenically unsaturated terminal group is at least one compound selected from the group consisting of compounds represented by the following formulas (IV), (V) and (VI):

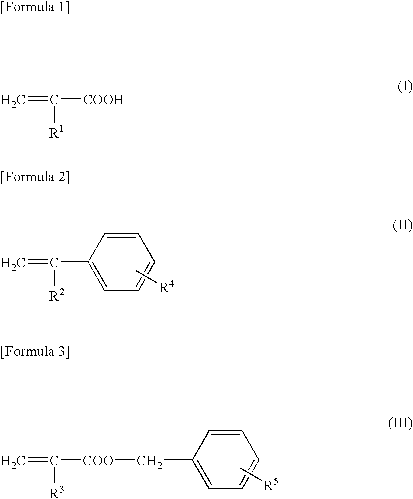

(R¹, R² and R³ each represents independently a hydrogen atom or a methyl group and may be the same or different, and R⁴ and R⁵ each represents independently a hydrogen atom, a halogen atom, a hydroxyl group, an alkyl group of 1-12 carbon atoms, an alkoxy group of 1-12 carbon atoms, a carboxyl group or a haloalkyl group),

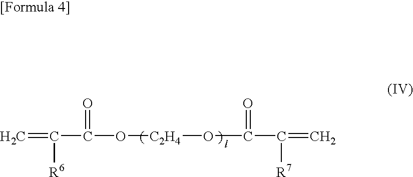

(R⁶ and R⁷ each represents independently a hydrogen atom or a methyl group and may be the same or different, and 1 is an integer of 3-15),

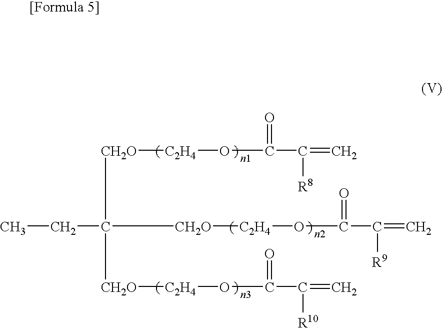

(in the formula, R⁸, R⁹ and R¹⁰ each represents independently a hydrogen atom or a methyl group and may be the same or different, and n1+n2+n3 is an integer of 1-20),

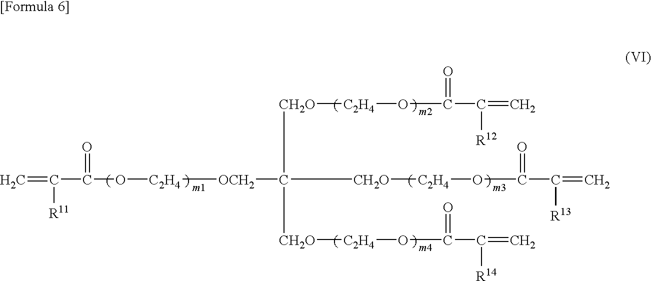

(in the formula, R¹¹, R¹², R¹³ and R¹⁴ each represents a hydrogen atom or a methyl group and may be the same or different, and m1+m2+m3+m4 is an integer of 1-20).

(2) A photosensitive resin composition described in the above (1) which contains 0.01-30% by mass of an acridine compound represented by the following formula (VII) as the photopolymerization initiator (c):

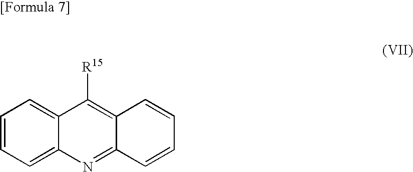

(in the formula, R¹⁵ is hydrogen, an alkyl group, an aryl group, a pyridyl group or an alkoxyl group).

(3) A photosensitive resin composition described in the above (1) or (2) which contains 0.01-30% by mass of (e) an N-aryl-α-amino acid compound.

(4) A photosensitive resin composition described in any one of the above (1)-(3) which contains 0.01-3% by mass of (f) a halogen compound.

(5) A photosensitive resin laminate comprising a support and the photosensitive resin composition described in any one of the above (1)-(4) and laminated on the support.

(6) A method for forming a resist pattern on a substrate which includes a lamination step of forming a photosensitive resin layer using the photosensitive resin laminate described in (5) on a substrate, an exposing step, and a developing step.

(7) A method for forming a resist pattern described in the above (6), wherein the exposure is carried out by direct drawing at the exposing step.

(8) A method for producing a printed wiring board which includes a step of etching or plating the substrate on which a resist pattern is formed by the method described in the above (6) or (7).

(9) A method for producing a lead frame which includes a step of etching the substrate on which a resist pattern is formed by the method described in the above (6) or (7).

(10) A method for producing a semiconductor package which includes a step of plating the substrate on which a resist pattern is formed by the method described in the above (6) or (7).

(11) A method for producing a bump which includes a step of plating the substrate on which a resist pattern is formed by the method described in the above (6) or (7).

(12) A method for producing a base having rugged pattern which includes a step of working by sandblasting the substrate on which a resist pattern is formed by the method described in the above (6) or (7).

### Advantages of the Invention

The photosensitive resin composition of the present invention shows excellent contrast performance just after exposure.

### BEST MODE FOR CARRYING OUT THE INVENTION

The present invention will be specifically explained below.

(a) Carboxyl Group-Containing Binder

The amount of carboxyl group contained in the carboxyl group-containing binder (a) used in the present invention is preferably not less than 100 and not more than 600, more preferably not less than 250 and not more than 450 in terms of acid equivalent. The acid equivalent means a mass of binder which has 1 equivalent of carboxyl group.

The carboxyl group in the binder is necessary for imparting developability and peelability with aqueous alkali solution to the photosensitive resin layer. The amount of carboxyl group is preferably not less than 100 for improving resistance to development, resolution and adhesion, and not more than 600 for improving developability and peelability. The measurement of acid equivalent is conducted by potentiometric titration method using sodium hydroxide of 0.1 mol/L with Hiranuma automatic titration apparatus (COM-555) manufactured by Hiranuma Sangyo Co., Ltd.

The weight-average molecular weight of the carboxyl group-containing binder (a) used in the present invention is not less than 5,000 and not more than 500,000. For improving developability, it is not more than 500,000, and not less than 5,000 for improving tenting film strength and inhibiting edge fusing. The weight-average molecular weight is more preferably not less than 20,000 and not more than 300,000. The edge fusing means a phenomenon that when a photosensitive resin laminate is wound up in the form of a roll, the photosensitive resin composition oozes out from the edge face of the roll.

Degree of dispersion (sometimes referred to as “molecular-weight distribution”) is expressed by a ratio of weight-average molecular weight and number-average molecular weight in the following formula. The degree of dispersion is preferably 1-10, more preferably 1-5.

Degree of dispersion=(weight-average molecular weight)/(number-average molecular weight)

The weight-average molecular weight and number-average molecular weight are obtained in terms of styrene by a gel permeation chromatography (GPC) manufactured by Japan Spectral Co., Ltd. (pump: Gulliver, PU-1580; columns: four columns of Shodex (trademark) manufactured by Showa Denko K.K. (KF-807, KF-806M, KF-806M, KF-802.5) which are in series; solvent for moving phase: tetrahydrofuran, using calibration curve of polystyrene standard sample (Shodex STANDARD SM-105 manufactured by Showa Denko K.K.).

The carboxyl group-containing binder (a) used in the present invention is a copolymer prepared by copolymerizing at least a monomer represented by the following formula (I) in an amount of 10-40% by mass, a monomer represented by the following formula (II) in an amount of 10-80% by mass and a monomer represented by the following formula (III) in an amount of 10-80% by mass (hereinafter referred to as “specific carboxylic group-containing binder”), and it has a weight-average molecular weight of 5,000-500,000.

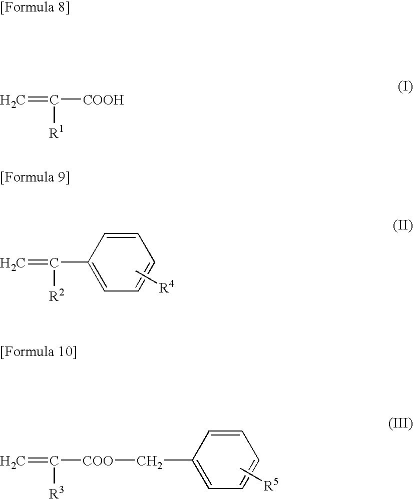

(R¹, R² and R³ each represents independently a hydrogen atom or a methyl group and may be the same or different, and R⁴ and R⁵ each represents independently a hydrogen atom, a halogen atom, a hydroxyl group, an alkyl group of 1-12 carbon atoms, an alkoxy group of 1-12 carbon atoms, a carboxyl group or a haloalkyl group).

An example of the monomer represented by the formula (I) is (meth)acrylic acid. In this case, the proportion of the monomer represented by the formula (I) is not less than 10% by mass and not more than 40% by mass, preferably not less than 20% by mass and not more than 40% by mass as a component of the copolymer. The proportion is not more than 40% by mass for improving resistance to development, resolution and adhesion, and not less than 10% by mass for improving developability and peelability with aqueous alkali solution. Hereinafter, the term “(meth)acrylic” means “acrylic” and “methacrylic”.

Examples of the monomer represented by the formula (II) are styrene, styrene derivatives such as α-methylstyrene, p-hydroxystyrene, p-methylstyrene, p-methoxystyrene and p-chlorostyrene. The proportion of the monomer represented by the formula (II) as a component of the copolymer is not less than 10% by mass and not more than 80% by mass, more preferably not less than 10% by mass and not more than 40% by mass. The proportion is preferably not less than 10% by mass from the points of resolution and adhesion, and not more than 80% by mass from the point of flexibility of hardened resist.

Examples of the monomer represented by the formula (III) are benzyl (meth)acrylate, 4-hydroxybenzyl (meth)acrylate, 4-methylbenzyl (meth)acrylate, and 4-chlorobenzyl (meth)acrylate, and benzyl (meth)acrylate is especially preferred from the viewpoints of developability and etchability, resistance at the plating step and maintenance of flexibility of hardened film.

The proportion of the monomer represented by the formula (III) in the carboxyl group-containing binder as a component of the copolymer is not less than 10% by mass and not more than 80% by mass, preferably not less than 10% by mass and not more than 70% by mass, more preferably not less than 30% by mass and not more than 70% by mass. The proportion is preferably not less than 10% by mass from the points of resolution and adhesion, and resistance to plating solution and preferably not more than 80% by mass from the point of developability.

The specific carboxyl group-containing binder used in the present invention may contain, in addition to the above monomers of the formulas (I)-(III) as essential components, other known monomers in an amount of 0-50% by mass, preferably 0-30% by mass as the components of the copolymer. As the other known monomers, mention may be made of, for example, monomers containing carboxylic acid such as fumaric acid, cinnamic acid, crotonic acid, itaconic acid, and half esters of maleic acid, and (meth)acrylic acid esters such as methyl (meth)acrylate, ethyl (meth)acrylate, n-propyl (meth)acrylate, cyclohexyl (meth)acrylate, n-butyl (meth)acrylate, 2-ethylhexyl (meth)acrylate, 2-hydroxyethyl (meth)acrylate, 2-hydroxypropyl (meth)acrylate, 4-hydroxybutyl (meth)acrylate, polyethylene glycol mono(meth)acrylate, polypropylene glycol mono(meth)acrylate, (meth)acrylamide, N-methylolacrylamide, N-butoxymethylacrylamide, (meth)acrylonitrile, and glycidyl (meth)acrylate. These may be used each alone or in combination of two or more.

The specific carboxyl group-containing binder used in the present invention can be synthesized by adding a suitable amount of a radical polymerization initiator such as benzoyl peroxide or azoisobutyronitrile to a solution obtained by diluting a mixture of the above monomers with a solvent such as acetone, methyl ethyl ketone or isopropanol, and then stirring the solution with heating. The binder can also be synthesized with dropping a part of the mixture to a reaction mixture. As synthesizing means, there may be employed bulk polymerization, suspension polymerization or emulsion polymerization as well as solution polymerization.

The proportion of the specific carboxyl group-containing binder used in the present invention in the whole photosensitive resin composition is preferably not less than 5% by mass and not more than 90% by mass, more preferably not less than 10% by mass and not more than 70% by mass, especially preferably not less than 20% by mass and not more than 60% by mass. It is not less than 5% by mass from the point of improvement of tenting film strength, and not more than 90% by mass from the point of improvement of developability.

In the composition of the present invention, there may be used, in combination with the above-mentioned specific carboxyl group-containing binder, other known carboxyl group-containing binder in a proportion of 0-85% by mass, preferably 0-50% by mass based on the whole photosensitive resin composition. As the other carboxyl group-containing binders usable in combination, mention may be made of, for example, copolymers of (meth)acrylic acid with at least one compound selected from the group consisting of (meth)acrylic acid ester compounds (e.g., methyl (meth)acrylate, ethyl (meth)acrylate, butyl (meth)acrylate, benzyl (meth)acrylate, and 2-hydroxyethyl (meth)acrylate), styrene and styrene derivatives, styrene/maleic anhydride copolymers, and celluloses containing carboxylic acid such as hydroxyethyl carboxymethyl cellulose. For inhibiting formation of agglomerates in developing solution, it is preferred to use in combination a thermoplastic polymer having a weight-average molecular weight of 30,000-90,000 which is obtained by copolymerizing methacrylic acid, styrene, 2-hydroxyethyl methacrylate and 2-ethylhexyl acrylate.

The content of the carboxyl group-containing binder (a) is not less than 20% by mass and not more than 90% by mass based on the whole photosensitive resin composition. From the viewpoint of the problem of edge fusing, it is not less than 20% by mass and from the viewpoint of hardenability, it is not more than 90% by mass.

(b) Addition-polymerizable monomer having at least one ethylenically unsaturated terminal group.

The addition-polymerizable monomer having at least one ethylenically unsaturated terminal group which is the component (b) used in the present invention contains at least one compound selected from the compounds represented by the following formulas (IV), (V) and (VI) as essential components.

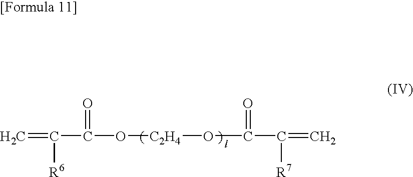

(R⁶ and R⁷ each represents independently a hydrogen atom or a methyl group and may be the same or different, and 1 is an integer of 3-15).

Examples of the compounds represented by the formula (IV) are tetraethylene glycol di(meth)acrylate, nonaethylene glycol di(meth)acrylate, and pentadecaethylene glycol di(meth)acrylate. These may be used each alone or in combination of two or more. Among them, nonaethylene glycol diacrylate is most preferred.

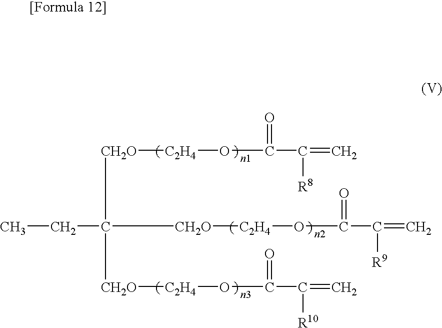

(in the formula, R⁸, R⁹ and R¹⁰ each represents independently a hydrogen atom or a methyl group and may be the same or different, and n1+n2+n3 is an integer of 1-20).

Examples of the compounds represented by the above formula (V) are polyethoxytrimethylolpropane tri(meth)acrylates. These may be used each alone or in combination of two or more. The value of n1+n2+n3 is preferably 3-9. Among them, triethoxytrimethylolpropane triacrylate is most preferred.

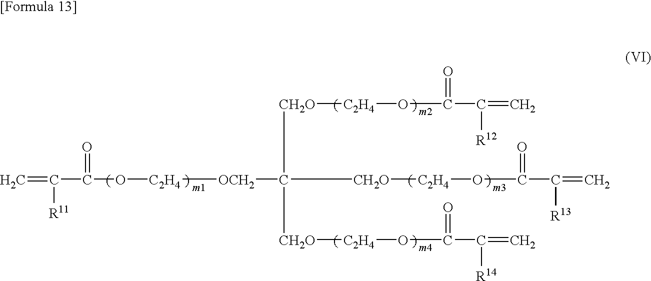

(in the formula, R¹¹, R¹², R¹³ and R¹⁴ each represents independently a hydrogen atom or a methyl group and may be the same or different, and m1+m2+m3+m4 is an integer of 1-20).

Examples of the compounds represented by the above formula (VI) are pentaerythritolpolyethoxy tetra(meth)acrylates. These may be used each alone or in combination of two or more. The value of m1+m2+m3+m4 is preferably 4-12. Among them, pentaerythritoltetraethoxy tetraacrylate is most preferred.

The amount of at least one compound selected from the group consisting of compounds represented by the above formulas (IV), (V) and (VI) which is contained in the photosensitive resin composition of the present invention is preferably 1-40% by mass, more preferably 5-30% by mass. The amount is preferably not less than 1% by mass for attaining good contrast after exposure and making minute the size of peeled pieces, and is preferably not more than 40% by mass for inhibiting edge fusing and deterioration of tenting property.

As the addition-polymerizable monomer having at least one ethylenically unsaturated terminal group which is the component (b) used in the present invention, there may be used known compounds having at least one ethylenically unsaturated terminal group which are not the same as the above-mentioned compounds.

Examples of the compounds are 4-nonylphenylheptaethylene glycol dipropylene glycol acrylate, 2-hydroxy-3-phenoxypropyl acrylate, phenoxyhexaethylene glycol acrylate, trimethylolpropane tri(meth)acrylate, pentaerythrytol tetra(meth)acrylate, reaction products of a half ester compound of phthalic anhydride and 2-hydroxypropyl acrylate with propylene oxide (trade name OE-A200 manufactured by Nippon Shokubai Kagaku Kogyo Co., Ltd.), 4-normaloctylphenoxypentapropylene glycol acrylate, 2,2-bis[{4-(meth)acryloxypolyethoxy}phenyl]propane, 2,2-bis{(4-acryloxypolyethoxy)cyclohexyl}propane or 2,2-bis{(4-methacryloxypolyethoxy)cyclohexyl}propane, 1,6-hexanediol (meth)acrylate, 1,4-cyclohexanediol di(meth)acrylate, or polyoxyalkylene glycol di(meth)acrylates, e.g., polypropylene glycol di(meth)acrylate, polyoxyethylenepolyoxypropylene glycol di(meth)acrylate and 2-di(p-hydroxyphenyl)propane di(meth)acrylate, glycerol tri(meth)acrylate, polyfunctional group (meth)acrylates containing urethane group such as urethanation products of hexamethylene diisocyanate and pentapropylene glycol monomethacrylate, and polyfunctional (meth)acrylates of isocyanuric acid ester compounds. These may be used each alone or combination of two or more.

The amount of the addition-polymerizable monomer having at least one ethylenically unsaturated terminal group contained as component (b) in the photosensitive resin composition of the present invention is in the range of 5-75% by mass, more preferably 15-70% by mass. The amount is preferably not less than 5% by mass for inhibiting insufficient hardening and prolongation of developing time, and is not more than 75% by mass for inhibiting occurrence of edge fusing and delay in peeling of hardened resist.

The proportion of at least one compound selected from the group consisting of compounds represented by the above formulas (IV), (V) and (VI) based on the total polymerizable monomer (b) contained in the photosensitive resin composition of the present invention is preferably 5-80% by mass, more preferably not less than 10% by mass.

(c) Photopolymerization Initiator

In the photosensitive resin composition of the present invention, there may be used generally known initiators as the photopolymerization initiator (c). The amount of the photopolymerization initiator (c) contained in the photosensitive resin composition of the present invention is 0.01-30% by mass, more preferably 0.05-10% by mass. The amount is preferably not less than 0.01% by mass for obtaining sufficient sensitivity, and preferably not more than 30% by mass for sufficiently transmitting the light up to the underside of resist and obtaining satisfactory high resolution.

Specific examples of the photopolymerization initiators are quinones such as 2-ethylanthraquinone, octaethylanthraquinone, 1,2-benzanthraquinone, 2,3-benzanthraquinone, 2-phenylanthraquinone, 2,3-diphenylanthraquinone, 1-chloroanthraquinone, 2-chloroanthraquinone, 2-methylanthraquinone, 1,4-naphthoquinone, 9,10-phenanthraquinone, 2-methyl-1,4-naphthoquinone, 9,10-phenanthraquinone, 2-methyl-1,4-naphthoquinone, 2,3-dimethylanthraquinone, and 3-chloro-2-methylanthraquinone, aromatic kinones such as benzophenone and Michler's ketone [4,4′-bis(methylamino)benzophenone], 4,4′-bis(diethylamino)benzophenone, dialkylketals such as benzoin, benzoin ethers such as benzoinethyl ether, benzoinphenyl ether, methylbenzoin, ethylbenzoin, benzyldimethyl ketal and benzyldiethyl ketal, thioxathones such as diethylthioxathone and chlorothioxathone, dialkylaminobenzoic acid esters such as ethyl dimethylaminobenzoate, oxime esters such as 1-phenyl-1,2-propanedione-2-O-benzoyloxime and 1-phenyl-1,2-propanedione-2-(O-ethoxycarbonyl)oxime, lophine dimmers such as 2-(o-chlorophenyl)-4,5-diphenylimidazolyl dimmer, 2-(o-chlorophenyl)-4,5-bis-(m-methoxyphenyl)imidazolyl dimmer and 2-(p-methoxyphenyl)-4,5-diphenylimidazolyl dimer, and acridine compounds shown below. These compounds may be used each alone or in combination of two or more.

The photosensitive resin composition of the present invention can contain an acridine compound represented by the following formula (VII) as the photopolymerization initiator (c), and the amount thereof is preferably 0.01-30% by mass, more preferably 0.05-10% by mass. The amount is preferably not less than 0.01% by mass for obtaining sufficient sensitivity and preferably not more than 30% by mass for sufficiently transmitting the light up to the underside of the resist and obtaining satisfactory high resolution.

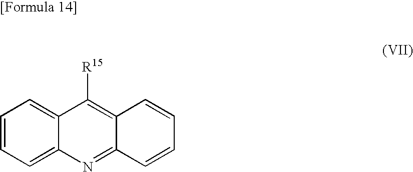

(in the formula, R¹⁵ represents hydrogen, an alkyl group, an aryl group, a pyridyl group or an alkoxyl group).

Examples of the acridine compound are acridine, 9-phenylacridine, 9-(p-methylphenyl)acridine, 9-(p-ethylphenyl)acridine, 9-(p-iso-propylphenyl)acridine, 9-(p-n-butylphenyl)acridine, 9-(p-tert-butylphenyl)acridine, 9-(p-methoxyphenyl)acridine, 9-(p-ethoxyphenyl)acridine, 9-(p-acetylphenyl)acridine, 9-(p-dimethylaminophenyl)acridine, 9-(p-cyanophenyl)acridine, 9-(p-chlorophenyl)acridine, 9-(p-bromophenyl)acridine, 9-(m-methylphenyl)acridine, 9-(m-n-propylphenyl)acridine, 9-(m-iso-propylpenyl)acridine, 9-(m-n-butylphenyl)acridine, 9-(m-tert-butylphenyl)acridine, 9-(m-methoxyphenyl)acridine, 9-(m-ethoxyphenyl)acridine, 9-(m-acetylphenyl)acridine, 9-(m-dimethylaminophenyl)acridine, 9-(m-diethylaminophenyl)acridine, 9-(cyanophenyl)acridine, 9-(m-chlorophenyl)acridine, 9-(m-bromophenyl)acridine, 9-methylacridine, 9-ethylacridine, 9-n-propylacridine, 9-iso-propylacridine, 9-cyanoethylacridine, 9-hydroxyethylacridine, 9-chloroethylacridine, 9-methoxyacridine, 9-ethoxyacridine, 9-n-propoxyacridine, 9-iso-propoxyacridine, 9-chloroethoxyacridine, and 9-pyridylacridine. Among them, 9-phenylacridine is preferred.

It is a preferred embodiment of the present invention for obtaining high sensitivity to use the acridine compound and the following halogen compound (f) in combination in the photosensitive resin composition. Moreover, it is a preferred embodiment of the present invention for obtaining high sensitivity to use the acridine compound, the following halogen compound (f) and additionally an N-aryl-α-amino acid compound (e) in combination in the photosensitive resin composition.

(d) Leuco Dyes

The photosensitive resin composition of the present invention contains a leuco dye (d) in an amount of 0.01-10% by mass. The leuco dyes include, for example, leuco crystal violet and fluoran dyes. Particularly, when leuco crystal violet is used, satisfactory contrast can be obtained, and use of leuco crystal violet is preferred. Examples of the fluoran dyes are 3-diethylamino-6-methyl-7-anilinofluoran, 3-dibutylamino-6-methyl-7-anilinofluoran, 2-(2-chloroanilino)-6-dibutylaminofluoran, 2-bromo-3-methyl-6-dibutylaminofluoran, 2-N,N-dibenzylamino-6-diethylaminofluoran, 3-diethylamino-7-chloroaminofluoran, 3,6-dimethoxyfluoran, and 3-diethylamino-6-methoxy-7-aminofluoran.

The content of the leuco dye (d) in the photosensitive resin composition is 0.01-10% by mass, preferably 0.5-6% by mass. The content is preferably not less than 0.01% by mass for producing satisfactory contrast, and is preferably not more than 10% by mass for maintaining storage stability.

It is a preferred embodiment of the present invention for obtaining good adhesion and contrast to use the leuco dye (d) and the following halogen compound (f) in combination in the photosensitive resin composition.

(e) N-aryl-α-amino Acid Compounds

The photosensitive resin composition of the present invention preferably contains an N-aryl-α-amino acid compound in an amount of 0.01-30% by mass in the composition. The content of N-aryl-α-amino acid compound is more preferably 0.05-10% by mass. The content is preferably not less than 0.01% by mass for obtaining sufficient sensitivity, and is preferably not more than 30% by mass for obtaining satisfactory resolution.

Examples of the N-aryl-α-amino acid compounds are N-phenylglycine, N-methyl-N-phenylglycine, N-ethyl-N-phenylglycine, N-(n-propyl)-N-phenylglycine, N-(n-butyl)-phenylglycine, N-(2-methoxyethyl)-N-phenylglycine, N-methyl-N-phenylalanine, N-ethyl-N-phenylalanine, N-(n-propyl)-phenylalanine, N-(n-butyl)-N-phenylalanine, N-methyl-N-phenylvaline, N-methyl-N-phenylleucine, N-methyl-N-(p-tolyl)glycine, N-ethyl-N-(p-tolyl)glycine, N-(n-propyl)-N-(p-tolyl)glycine, N-(n-butyl)-N-(p-tolyl)-glycine, N-methyl-N-(n-chlorophenyl)glycine, N-ethyl-N-(p-chlorophenyl)glycine, N-(n-propyl)-N-(p-chlorophenyl)glycine, N-(n-butyl)-N-(p-chlorophenyl)glycine, N-methyl-N-(p-bromophenyl)glycine, N-ethyl-N-(p-bromophenyl)glycine, N-(n-propyl)-N-(p-bromophenyl)glycine, N-(n-butyl)-N-(p-bromophenyl)glycine, N,N′-diphenylglycine, N-(p-chlorophenyl)glycine, N-(p-bromophenyl)glycine, and N-(o-chlorophenyl)glycine. Among them, N-phenylglycine is especially preferred.

(f) Halogen Compounds

The photosensitive resin composition of the present invention preferably contains a halogen compound in an amount of 0.01-3% by mass. The content of the halogen is more preferably 0.1-1.5% by mass. The content of the halogen compound is preferably not less than 0.01% by mass from the point of photo-hardenability, and preferably not more than 3% by mass from the point of storage stability of resist.

Examples of the halogen compounds are amyl bromide, isoamyl bromide, isobutylene bromide, ethylene bromide, diphenylmethyl bromide, benzyl bromide, methylene bromide, tribromomethylphenyl sulfone, carbon tetrabromide, tris(2,3-dibromopropyl)phosphate, trichloroacetamide, amyl iodide, isobutyl iodide, 1,1,1-trichloro-2,2-bis(p-chlorophenyl)ethane, and chlorinated triazine compounds. Among them, tribromomethylphenyl sulfone is particularly preferred.

(g) Other Components

For improving handleability of the photosensitive resin composition of the present invention, it is also possible to add the following coloring materials in addition to the leuco dye (d). Examples of the coloring materials are fuchsin, Phthalocyanine Green, Auramine base, paramagenta, Crystal Violet, Methyl Orange, Nile Blue 2B, Victoria Blue, Malachite Green (AIZEN (trademark) MALACHITE GREEN manufactured by Hodogaya Chemical Co., Ltd.), Basic Blue 20, and Diamond Green (AIZEN (trademark) DIAMOND GREEN GH manufactured by Hodogaya Chemical Co., Ltd.).

The amount of the coloring material if added is preferably 0.001-1% by mass in the photosensitive resin composition. When the content is not less than 0.001 by mass, handleability is improved, and when it is not more than 1% by mass, storage stability is maintained.

Furthermore, for improving heat stability and storage stability of the photosensitive resin composition of the present invention, it is preferred that the photosensitive resin composition contains at least one compound selected from the group consisting of a radical polymerization inhibitor, benzotriazole and carboxybenzotriazole.

Examples of the radical polymerization inhibitors are p-methoxyphenol, hydroquinone, pyrogallol, naphthylamine, tert-butylcatechol, cuprous chloride, 2,6-di-tert-butyl-p-cresol, 2,2′-methylenebis(4-methyl-6-tert-butylphenol), 2,2′-methylenebis(4-ethyl-6-tert-butylphenol), nitrosophenylhydroxyamine aluminum salt, and diphenylnitrosoamine.

Examples of the benzotriazoles are 1,2,3-benzotriazole, 1-chloro-1,2,3-benzotriazole, bis(N-2-ethylhexyl)aminomethylene-1,2,3-benzotriazole, bis(N-2-ethylhexyl)aminomethylene-1,2,3-tolyltriazole, and bis(N-2-hydroxyethyl)aminomethylene-1,2,3-benzotriazole.

Examples of the carboxybenzotriazoles are 4-carboxy-1,2,3-benzotriazole, 5-carboxy-1,2,3-benzotriazole, N-(N,N-di-2-ethylhexyl)aminomethylenecarboxybenzotriazole, N-(N,N-di-2-hydroxyethyl)aminomethylenecarboxybenzotriazole, and N-(N,N-di-2-ethylhexyl)aminoethylenecarboxybenzotriazole.

The total amount of the radical polymerization inhibitor, benzotriazole and carboxybenzotriazole is preferably 0.01-3% by mass, more preferably 0.05-1% by mass. This amount is preferably not less than 0.01% by mass for imparting storage stability to the photosensitive resin composition and more preferably not more than 3% by mass for maintaining sensitivity.

If necessary, the photosensitive resin composition of the present invention may contain a plasticizer. Examples of the plasticizers are polyethylene glycol, polypropylene glycol, polyoxypropylenepolyoxyethylene ether, polyoxyethylenemonomethyl ether, polyoxypropylenemonomethyl ether, polyoxyethylenepolyoxypropylenemonomethyl ether, polyoxyethylenemonoethyl ether, polyoxypropylenemonoethyl ether, polyoxyethylenepolyoxypropylenemonoethyl ether, diethyl phthalate, o-toluenesulfonic acid amide, p-toluenesulfonic acid amide, tributyl citrate, triethyl citrate, triethyl acetylcitrate, tri-n-propyl acetylcitrate, and tri-n-butyl acetylcitrate.

The amount of the plasticizer is preferably 5-50% by mass, more preferably 5-30% by mass in the photosensitive resin composition. The amount is preferably not less than 5% by mass for inhibiting retardation of developing time and imparting flexibility to hardened film, and is preferably not more than 50% by mass for inhibiting insufficient hardening and edge fusing.

<Solution of Photosensitive Resin Composition>

The photosensitive resin composition of the present invention may be in the form of a solution of photosensitive resin composition with addition of a solvent. Suitable solvents are ketones represented by methyl ethyl ketone (MEK), and alcohols such as methanol, ethanol and isopropyl alcohol. It is preferred to add the solvent to the solution of the photosensitive resin composition so that the solution has a viscosity of 500-4000 mPa·sec at 25° C.

<Photosensitive Resin Laminate>

The photosensitive resin laminate of the present invention comprises a photosensitive resin layer and a support which supports the layer, and if necessary, it may have a protective layer on the surface of the photosensitive resin layer opposite to the surface on which the support is present.

The support used here is desirably a transparent support which transmits the light emitted from exposure light source. Examples of the supports are polyethylene terephthalate film, polyvinyl alcohol film, polyvinyl chloride film, vinyl chloride copolymer film, polyvinylidene chloride film, vinylidene chloride copolymer film, polymethyl methacrylate copolymer film, polystyrene film, polyacrylonitrile film, styrene copolymer film, polyamide film, and cellulose derivative film. If necessary, these films may be stretched. They have a haze of preferably 5 or less. The thinner film is more advantageous from the point of image formability and economical viewpoint, and those of 10-30 μm in thickness are preferred for maintaining strength.

The important characteristic of the protective layer used for the photosensitive resin laminate is that the protective layer is sufficiently smaller than the support in adhesion to photosensitive resin layer, and can be easily peeled off. For example, polyethylene film and polypropylene film can be preferably used as the protective layer. Furthermore, a film which is disclosed in JP-A-59-202457 and is excellent in peelability can be used. Thickness of the protective layer is preferably 10-100 μm, more preferably 10-50 μm.

Thickness of the photosensitive resin layer in the photosensitive resin laminate is preferably 5-100 μm, more preferably 7-60 μm. The smaller the thickness, the higher the resolution, and the larger the thickness, the higher the film strength. Therefore, the thickness can be optionally selected depending on the use.

For producing the photosensitive resin laminate of the present invention, there can be employed conventionally known method of laminating in succession the support, the photosensitive resin layer, and, if necessary, the protective layer.

For example, a photosensitive resin composition used for the photosensitive resin layer is made into the above-mentioned solution of photosensitive resin composition, and first the solution is coated on the support by a bar coater, a roll coater or the like and dried to laminate on the support a photosensitive resin layer comprising the photosensitive resin composition.

Then, if necessary, the protective layer is laminated on the photosensitive resin layer, whereby a photosensitive resin laminate can be produced.

<Method for Forming Resist Pattern>

The resist pattern using the photosensitive resin laminate of the present invention can be formed by the steps including a laminating step, an exposing step and a developing step.

First, the laminating step is carried out using a laminator. If the photosensitive resin laminate has a protective layer, the protective layer is peeled off, and then the photosensitive resin layer is laminated by contact bonding the layer under pressure and heating onto the surface of a substrate. In this case, the photosensitive resin layer may be laminated on only one side or, if necessary, on both sides of the substrate. The heating temperature in this case is generally 40-160° C. Furthermore, adhesion of the resulting resist pattern to the substrate can be improved by carrying out the contact bonding twice or more. In this case, the contact bonding may be carried out by using a two-stage laminator provided with double rolls or passing between rolls repeatedly some times.

Next, the exposing step is carried out using an exposing machine. If necessary, the support is peeled off and exposure is carried out through a photomask with actinic rays. The exposure is determined by illuminance of light source and exposing time. It may be measured using an actinometer.

A maskless exposing method may be employed at the exposing step. The maskless exposure is carried out by direct drawing on the substrate using a direct drawing device without using a photomask. As a light source, there are used semiconductor laser of 350-410 nm in wavelength or an ultra-high pressure mercury lamp. The drawn pattern is controlled by a computer, and the exposure in this case is determined by illuminance of light source and moving speed of the substrate.

Next, the developing step is carried out using a developing apparatus. In case there is a support on the photosensitive resin layer after exposure, the support is removed. Successively, unexposed portions are removed by development with a developing solution comprising an aqueous alkali solution to obtain a resist image. The aqueous alkali solution is preferably an aqueous solution of Na₂CO₃ or K₂CO₃. The developing solution is selected in accordance with the characteristics of the photosensitive resin layer, and generally an aqueous solution of Na₂CO₃ having a concentration of 0.2-2% by mass is used. The aqueous alkali solution may contain a surface active agent, an anti-foaming agent, a small amount of an organic solvent for acceleration of development. The developing solution at the developing step is preferably kept at a constant temperature in the range of 20-40° C.

A resist pattern is obtained by the above steps, and in some cases, there may be carried out a heating step of heating the resist pattern to 100-300° C. By carrying out this heating step, chemical resistance can be further improved. The heating is performed by using heating ovens such as hot-air, infrared and far infrared type ovens.

<Method for Making Printed Wiring Board>

The method for making a printed wiring board according to the present invention is carried out by forming a resist pattern on a copper-clad laminate plate or a flexible substrate as substrate by the above-mentioned method for formation of resist pattern and thereafter carrying out the following steps.

First, a step is carried out which comprises forming a conductor pattern by subjecting the copper surface of the substrate exposed by development to known methods such as etching method, plating method, etc.

Thereafter, a peeling step of peeling off the resist pattern from the substrate with an aqueous solution having an alkalinity stronger than that of the developing solution is carried out to obtain a desired printed wiring board. The aqueous alkali solution used for peeling (hereinafter sometimes referred to as “peeling solution”) is not particularly limited, and an aqueous solution of NaOH or KOH of 2-5% by mass in concentration is generally used. It is also possible to add a small amount of a water-soluble solvent to the peeling solution. The temperature of the peeling solution at the peeling step is preferably 40-70° C.

<Method for Making Lead Frame>

The method for making a lead frame according to the present invention is carried out by forming a resist pattern on a metal plate such as of copper, copper alloy or iron alloy as substrate by the above-mentioned method for formation of resist pattern and thereafter carrying out the following steps.

First, a step is carried out which comprises forming a conductor pattern by etching the substrate exposed by development. Thereafter, a peeling step of peeling off the resist pattern by the same method as in making the printed wiring board is carried out to obtain a desired lead frame.

<Method for Making Semiconductor Package>

The method for making a semiconductor package according to the present invention is carried out by mounting a chip in which formation of circuit as LSI has been completed by the following steps.

First, the portion where metal of substrate is exposed on the substrate having the resist patter obtained by development is subjected to plating with copper sulfate to form a conductor pattern. Thereafter, a peeling step of peeling off the resist pattern by the same method as in making the printed wiring board is carried out and further the portion other than columnar plating is subjected to etching for removing the thin metal layer, and the above-mentioned chip is mounted, thereby obtaining a desired semiconductor package.

<Method for Making Bump>

The method for making a bump according to the present invention is carried out for mounting a chip in which formation of circuit as LSI has been completed by the following steps.

First, the portion where metal of substrate is exposed on the substrate having the resist patter obtained by development is subjected to plating with copper sulfate to form a conductor pattern. Thereafter, a peeling step of peeling off the resist pattern by the same method as in making the printed wiring board is carried out and further the thin metal layer of the portion other than columnar plating is removed by etching, thereby obtaining a desired bump.

<Method for Making Substrate Having Rugged Pattern>

The resist pattern formed by the above resist pattern forming method can be used as a protective mask member in working a substrate by sandblasting method.

As the substrates, mention may be made of, for example, those of glass, silicon wafer, amorphous silicon, polycrystalline silicon, ceramics, sapphire, and metallic material. A resist pattern is formed on the substrate by the same method as the above resist pattern forming method. Thereafter, a sandblasting step of cutting to a desired depth by spraying a blasting material to the formed resist pattern from above and a peeling step of peeling off the resist pattern portion remaining on the substrate from the substrate with an alkali peeling solution are conducted to obtain a substrate having fine rugged pattern. As the blasting material used at the sandblasting step, there may be used known blasting materials such as fine particles of about 2-100 μm of SiC, SiO₂, Al₂O₃, CaCO₃, ZrO, glass, stainless steel, etc.

The above method for making a substrate having rugged pattern by sandblasting method can be used for producing partition walls of flat panel display, glass cap working of organic EL, drilling of silicon wafer, and pin raising of ceramics. Furthermore, it can be utilized for making ferroelectric films and electrodes of metallic material layer selected from the group consisting of noble metals, noble metal alloys, high-melting point metals and high-melting point metal compounds.

### Examples

Examples of embodiments of the present invention will be specifically explained below.

### Examples 1-12 and Comparative Examples 1-2

First, the method for preparing samples used for evaluation in Examples and Comparative Examples will be explained, and then the method of evaluation of the samples and the results of evaluation will be explained.

1. Preparation of Samples for Evaluation

The photosensitive resin laminates in Examples and Comparative Examples were prepared in the following manner.

<Preparation of Carboxyl Group-Containing Binder>

First, a binder shown below was prepared.

### Preparation Example

In a four-necked flask of 1000 cc provided with a nitrogen-introduction port, a stirring blade, a Dimroth and a thermometer was charged 300 g of methyl ethyl ketone in a nitrogen atmosphere, and temperature of water-bath was raised to 80° C. Then, 400 g in total of a solution having a compositional ratio of methacrylic acid/styrene/benzyl methacrylate of 30/20/50 (by mass) was prepared. A solution was prepared by dissolving 3 g of azobisisobutyronitrile in 30 g of methyl ethyl ketone, and the resulting solution was dropped to the solution prepared previously over 2 hours while stirring. Thereafter, polymerization was carried out for 6 hours (primary polymerization). Thereafter, a solution prepared by dissolving 6 g of azobisisobutyronitrile in 30 g of methyl ethyl ketone was dropped dividedly three times at a 4 hours' interval, followed by stirring with heating for 5 hours (secondary polymerization). Then, 240 g of methyl ethyl ketone was added, and the polymerization reaction product was taken out of the flask to obtain a binder solution B-1. This binder solution had a weight-average molecular weight of 55,000, a dispersion degree of 2.6 and an acid equivalent of 290. Methyl ethyl ketone in the resulting binder solution B-1 was sufficiently removed, and resin solid content measured was 41.1% by mass.

In the same manner, binder solutions B-2-B-4 were prepared. Compositional ratio of the polymeric material and resin solid content, weight-average molecular weight, dispersion degree, and acid equivalent of the resulting binder solutions are shown below.

Binder B-1: methacrylic acid/styrene/benzyl methacrylate=30/20/50 (weight ratio) (weight-average molecular weight 55,000, dispersion degree 2.6, acid equivalent 290, solid concentration=41% by mass in methyl ethyl ketone solution)

Binder B-2: methacrylic acid/methyl methacrylate/n-butyl acrylate=25/65/10 (weight ratio) (weight-average molecular weight 80,000, dispersion degree 3.7, acid equivalent 374, solid concentration=34% by mass in methyl ethyl ketone solution)

Binder B-3: methacrylic acid/methyl methacrylate/styrene=25/50/25 (weight ratio) (weight-average molecular weight 50,000, dispersion degree 3.1, acid equivalent 344, solid concentration=43% by mass in methyl ethyl ketone solution)

Binder B-4: methacrylic acid/benzyl methacrylate/styrene/methyl methacrylate=25/35/30/10 (weight ratio) (weight-average molecular weight 55,000, dispersion degree 2.3, acid equivalent 344, solid concentration=41% by mass in methyl ethyl ketone solution)

<Production of Photosensitive Resin Laminate>

A photosensitive resin composition having a composition shown in Table 1 and a solvent were well stirred and mixed to prepare a solution of the photosensitive resin composition, and the solution was uniformly coated by a bar coater on the surface of a polyethylene terephthalate film of 16 μm in thickness as a support, and dried in a dryer of 95° C. for 4 minutes to form a photosensitive resin layer. The thickness of the photosensitive resin layer was 40 μm.

Then, a polyethylene film of 23 μm in thickness as a protective layer was laminated on the surface of the photosensitive resin layer on which the polyethylene terephthalate film was not laminated to obtain a photosensitive resin laminate.

Name of the component in the solution of photosensitive resin composition indicated by abbreviation in Table 1 is shown in Table 2.

The values for B-1-B-4 in Table 1 indicate solid contents.

TABLE 1

| | | Example 1 | Example 2 | Example 3 | Example 4 | Example 5 | Example 6 | Example 7 | Example 8 |
|---|---|---|---|---|---|---|---|---|---|
| Photosensitive | B-1 | 55 | 55 | 66 | 55 | 55 | 55 | 55 | 55 |
| resin | B-2 | | | | | | | | |
| Composition | B-3 | | | | | | | | |
| (part by mass) | B-4 | | | | | | | | |
| | M-1 | 30 | 30 | | | 10 | 10 | 10 | 10 |
| | M-2 | | | 30 | | | | | |
| | M-3 | | | | 30 | | | | |
| | M-4 | 10 | 10 | 10 | 10 | 30 | | | |
| | M-5 | | | | | | 30 | | |
| | M-6 | | | | | | | 30 | 20 |
| | M-7 | | | | | | | | 10 |
| | M-8 | | | | | | | | |
| | M-9 | | | | | | | | |
| | I-1 | 4 | | | | | | | |
| | I-2 | 0.2 | | | | | | | |
| | I-3 | | 1 | 1 | 1 | 1 | 1 | 1 | 1 |
| | I-4 | | 0.25 | 0.25 | 0.25 | 0.25 | 0.25 | 0.25 | 0.25 |
| | I-5 | | 1 | 1 | 1 | 1 | 1 | 1 | 1 |
| | D-1 | 0.05 | 0.05 | 0.05 | 0.05 | 0.05 | 0.05 | 0.05 | 0.05 |
| | D-2 | 0.6 | 0.5 | 0.5 | 0.5 | 0.5 | 0.5 | 0.5 | 0.5 |
| Contrast | ΔE | 10 | 3.5 | 3.4 | 3.2 | 2.4 | 2.9 | 2.7 | 2.6 |
| | Rank | ⊚ | ⊚ | ⊚ | ⊚ | ◯ | ◯ | ◯ | ◯ |
| Resolution | μm | 30 | 30 | 25 | 25 | 25 | 28 | 28 | 25 |
| | Rank | ◯ | ◯ | ⊚ | ⊚ | ⊚ | ◯ | ◯ | ⊚ |
| Adhesion | μm | 20 | 30 | 25 | 25 | 25 | 28 | 30 | 28 |
| | Rank | ⊚ | ◯ | ⊚ | ⊚ | ⊚ | ◯ | ◯ | ◯ |
| Development | mg | 18 | 8 | 7 | 9 | 12 | 30 | 10 | 10 |
| agglomeration | Rank | ⊚ | ⊚ | ⊚ | ⊚ | ⊚ | ◯ | ⊚ | ⊚ |
| Tenting | % | 0.4 | 0.4 | 0.4 | 0.4 | 0.4 | 0 | 0 | 0 |
| property | Rank | ◯ | ◯ | ◯ | ◯ | ◯ | ⊚ | ⊚ | ⊚ |
| Size of | Rank | ⊚ | ⊚ | ◯ | ◯ | ◯ | ◯ | ◯ | ◯ |
| exfoliated piece | | | | | | | | | |

| | | | | | | Comparative | Comparative |
|---|---|---|---|---|---|---|---|
| | | Example 9 | Example 10 | Example 11 | Example 12 | Example 1 | Example 2 |
| Photosensitive | B-1 | 35 | 15 | | 55 | | 55 |
| resin | B-2 | 20 | 40 | | | | |
| Composition | B-3 | | | | | 55 | |
| (part by mass) | B-4 | | | 55 | | | |
| | M-1 | 10 | 10 | 30 | | 30 | |
| | M-2 | | | | | | |
| | M-3 | | | | | | |
| | M-4 | 15 | 15 | 10 | 10 | 10 | 10 |
| | M-5 | 10 | 10 | | | | |
| | M-6 | | | | | | 30 |
| | M-7 | | | | | | |
| | M-8 | 5 | 5 | | | | |
| | M-9 | | | | 30 | | |
| | I-1 | | | | | | |
| | I-2 | | | | | | |
| | I-3 | 1 | 1 | 1 | 1 | 1 | 1 |
| | I-4 | 0.25 | 0.25 | 0.25 | 0.25 | 0.25 | 0.25 |
| | I-5 | 1 | 1 | 1 | 1 | 1 | 1 |
| | D-1 | 0.05 | 0.05 | 0.05 | 0.05 | 0.05 | 0.05 |
| | D-2 | 0.5 | 0.5 | 0.5 | 0.5 | 0.5 | 0.5 |
| Contrast | ΔE | 2.6 | 2.5 | 3.5 | 3.4 | 1.1 | 1.2 |
| | Rank | ◯ | ◯ | ⊚ | ⊚ | X | X |
| Resolution | μm | 25 | 28 | 30 | 28 | 25 | 28 |
| | Rank | ⊚ | ◯ | ◯ | ◯ | ⊚ | ⊚ |
| Adhesion | μm | 25 | 28 | 30 | 28 | 25 | 30 |
| | Rank | ⊚ | ◯ | ◯ | ◯ | ⊚ | ◯ |
| Development | mg | 15 | 18 | 8 | 6 | 77 | 16 |
| agglomeration | Rank | ⊚ | ⊚ | ⊚ | ⊚ | X | ⊚ |
| Tenting | % | 0 | 0.4 | 0.4 | 0.4 | 0.4 | ◯ |
| property | Rank | ⊚ | ◯ | ◯ | ◯ | ◯ | ⊚ |
| Size of | Rank | ◯ | ◯ | ⊚ | ◯ | X | X |
| exfoliated piece | | | | | | | |

TABLE 2

| Marks | Components |
|---|---|
| B-1 | 41% by mass(solid content) methyl ethyl ketone solution of |
| | copolymer having a composition of methacrylic |
| | acid/styrene/benzyl methacrylate (30/20/50 in mass ratio) |
| | and having an acid equivalent of 290, and a weight-average |
| | molecular weight of 55,000 |
| B-2 | 34% by mass(solid content) methyl ethyl ketone solution of |
| | copolymer having a composition of methacrylic acid/methyl |
| | methacrylate/n-butyl acrylate (25/65/10 in mass ratio) and |
| | having an acid equivalent of 374, and a weight-average |
| | molecular weight of 80,000 |
| B-3 | 43% by mass(solid content) methyl ethyl ketone solution of |
| | copolymer having a composition of methacrylic acid/methyl |
| | methacrylate/styrene (25/50/25 in mass ratio) and having an |
| | acid equivalent of 344, and a weight-average molecular |
| | weight of 50,000 |
| B-4 | 41% by mass(solid content) methyl ethyl ketone solution of |
| | copolymer having a composition of methacrylic acid/benzyl |
| | methacrylate/styrene/methyl methacrylate (25/35/30/10 in |
| | mass ratio) and having an acid equivalent of 344, and a |
| | weight-average molecular weight of 55,000 |
| M-1 | Nonaethylene glycol diacrylate |
| M-2 | Triacrylate obtained by adding 3 moles in average of |
| | ethylene oxide to trimethylolpropane |
| M-3 | Tetraacrylate of glycol obtained by adding 4 moles in |
| | average of ethylene oxide to pentaerythritol |
| M-4 | (2,2-bis{4-(methacryloxypentaethoxy)phenyl}propane |
| M-5 | Dimethacrylate of polypropylene glycol obtained by adding 2 |
| | moles in average of propylene oxide to both ends of |
| | bisphenol A and dimethacrylate of polyethylene glycol |
| | obtained by adding 15 moles in average of ethylene oxide to |
| | both ends of bisphenol A |
| M-6 | Dimethacrylate of polyalkylene glycol obtained by further |
| | adding 3 moles of ethylene oxide to both ends of propylene |
| | glycol obtained by adding 12 moles in average of propylene |
| | oxide |
| M-7 | Heptapropylene glycol dimethacrylate |
| M-8 | 4-Nonylphenylheptaethylene glycol dipropylene glycol |
| | acrylate |
| M-9 | Triacrylate obtained by adding 20 moles in total of |
| | ethylene oxide to trimethylolpropane (SR-415 manufactured |
| | by Sartomer Co.) |
| I-1 | 2,2′-bis(2-chlorophenyl)-4,4′,5,5′-tetraphenyl-1,1′- |
| | bisimidazole |
| I-2 | 4,4′-bis(diethylamino)benzophenone |
| I-3 | 9-Phenylacridine |
| I-4 | N-phenylglycine |
| I-5 | Tribromomethylphenyl sulfone |
| D-1 | Diamond Green |
| D-2 | Leuco Crystal violet |

<Adjustment of Substrate Surface>

As a substrate for evaluation, a copper-clad laminate plate of 1.6 mm thick having a rolled copper foil of 35 μm thick was used, and the surface thereof was subjected to wet buff roll polishing (passed twice through Scotch Brite (trademark) HD#600 manufactured by 3M Co., Ltd.).

<Lamination>

While peeling off the polyethylene film of the photosensitive resin laminate, the photosensitive resin laminate was laminated on the copper-clad laminate plate the surface of which was adjusted and which was preheated to 60° C. by a hot roll laminator (AL-70 manufactured by Asahi Kasei Electronics Co., Ltd.) at a roll temperature of 105° C. The air pressure was 0.35 MPa, and laminating speed was 1.5 m/min.

<Exposure>

In Example 1, a pattern mask necessary for evaluation was placed on the polyethylene terephthalate film which was a support of photosensitive resin layer, followed by exposing with an ultra-high pressure mercury lamp (HMW-201KB manufactured by Oak Mfg. Co., Ltd.) at an exposure of 50 mJ/cm². In Examples 2-11 and Comparative Examples 1-2, exposure was carried out by a direct drawing type exposing device (DI exposing machine DE-1AH manufactured by PHC Co., Ltd., light source: GaN bluish purple diode, main wavelength 407±3 nm) at an exposure of 25 mJ/cm².

<Development>

After the polyethylene terephthalate film was peeled off, the photosensitive resin layer was sprayed with 1% by mass aqueous Na₂CO₃ solution of 30° C. for a given time to dissolve and remove the unexposed portion. In this case, the minimum time required for completely dissolving the photosensitive resin layer of unexposed portion is taken as the minimum developing time.

2. Evaluation Methods

The evaluation methods are shown below.

(1) Contrast

The color difference ΔE between the unexposed portion of the photosensitive resin layer after lapse of 15 minutes from lamination and the exposed portion of the photosensitive resin layer after lapse of 30 seconds from exposure was measured by a color difference meter (NF333 simple spectral color difference meter manufactured by Nippon Denshoku Co., Ltd.), and it was ranked as follows.

⊚: The value ΔE exceeds 3.

◯: The value ΔE exceeds 2, and is not more than 3.

×: The value ΔE is not more than 2.

(2) Resolution

A substrate for evaluation of sensitivity and resolution after lapse of 15 minutes from lamination was exposed through a line pattern mask having a ratio of 1:1 of the width of exposed portion and that of unexposed portion. This was developed for a developing time twice the minimum developing time, and the minimum width of mask line in which the hardened resist line was normally formed was taken as a value of resolution and ranked in the following manner.

⊚: The value of resolution is not more than 25 μm.

◯: The value of resolution exceeds 25 μm, and is not more than 30 μm.

×: The value of resolution exceeds 30 μm.

(3) Adhesion

A substrate for evaluation of sensitivity and resolution after lapse of 15 minutes from lamination was exposed through a line pattern mask having a ratio of 1:1 of the width of exposed portion and that of unexposed portion. This was developed for a developing time twice the minimum developing time, and the minimum width of mask line in which the hardened resist line was normally formed was taken as a value of adhesion and ranked in the following manner.

⊚: The value of adhesion is not more than 25 μm.

◯: The value of adhesion exceeds 25 μm, and is not more than 30 μm.

×: The value of adhesion exceeds 30 μm.

(4) Development Agglomeration

6 g of unexposed photosensitive resin layer was dissolved and dispersed in 200 ml of 1% aqueous sodium carbonate solution. This solution was continuously sprayed for 8 hours by a developing solution circulating apparatus equipped with a pump and a spray nozzle (spraying pressure=0.2 MPa) and then filtered with a Millipore filter of 5 μm. Dry weight of a development agglomerate collected on a filter paper was measured, and ranked as follows.

⊚: The weight of the development agglomerate is not more than 20 mg.

◯: The weight of the development agglomerate exceeds 20 mg, and is not more than 40 mg.

×: The weight of the development agglomerate exceeds 40 mg.

(5) Tenting Property

A photosensitive resin layer was laminated on both sides of a substrate which was a copper-clad laminate plate of 1.6 mm thick having a hole of 6 mm in diameter, followed by exposing and developing for a developing time which was twice the minimum developing time. The number of film breaks was measured, and the rate of film breaks was calculated by the following formula and ranked as follows.

Rate of tenting film breaks (%)=[the number of film breaks/total number of tenting films]×100

⊚: The rate of tenting film breaks is 0%.

◯: The rate of tenting film breaks exceeds 0%, and is not more than 0.5%.

×: The rate of tenting film breaks exceeds 0.5%.

(6) Size of Exfoliated Piece

A laminate plate of 4.2 cm×6 cm, the whole surface of which was exposed, was dipped in an aqueous sodium hydroxide solution (50° C., 3% by mass), and shape of hardened film which exfoliated from the laminate plate (size of exfoliated piece) was ranked as follows.

⊚: The size of exfoliated piece is not more than 5 mm square.

◯: The size of exfoliated piece exceeds 5 mm square, and is not more than 10 mm square.

×: The size of exfoliated piece exceeds 10 mm square.

3. Results of Evaluation

The results in Examples and Comparative Examples are shown in Table 1.

### INDUSTRIAL APPLICABILITY

The present invention can be utilized for production of printed wiring board, production of lead frame for mounting IC chip, precision working of metal foil such as production of metal mask, production of semiconductor package such as BGA and CSP, production of tape substrates such as COF and TAB, production of semiconductor bump, production of ITO electrode or address electrode, production of partition wall of flat panel display such as electromagnetic wave shield, and production of substrate having rugged pattern by sandblasting method.

1. A photosensitive resin composition which comprises (a) 20-90% by mass of a carboxyl group-containing binder, (b) 5-75% by mass of an addition-polymerizable monomer having at least one ethylenically unsaturated terminal group, (c) 0.01-30% by mass of a photopolymerization initiator, and (d) 0.01-10% by mass of a leuco dye, wherein (a) the carboxyl group-containing binder has a weight-average molecular weight of 5,000-500,000 and contains a copolymer obtained by copolymerizing at least a monomer represented by the following formula (I) in an amount of 10-40% by mass, a monomer represented by the following formula (II) in an amount of 10-80% by mass and a monomer represented by the following formula (III) in an amount of 10-80% by mass, and (b) the addition-polymerizable monomer having at least one ethylenically unsaturated terminal group is at least one compound selected from the group consisting of compounds represented by the following formulas (IV), (V) and (VI): 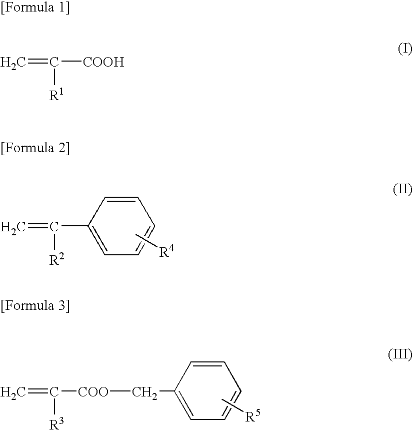
(R¹, R² and R³ each represents a hydrogen atom or a methyl group and may be the same or different, and R⁴ and R⁵ each represents independently a hydrogen atom, a halogen atom, a hydroxyl group, an alkyl group of 1-12 carbon atoms, an alkoxy group of 1-12 carbon atoms, a carboxyl group or a haloalkyl group), 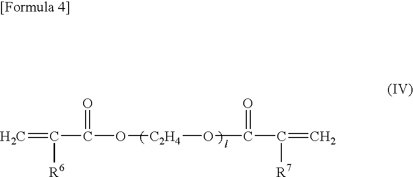
(R⁶ and R⁷ each represents a hydrogen atom or a methyl group and may be the same or different, and 1 is an integer of 3-15), 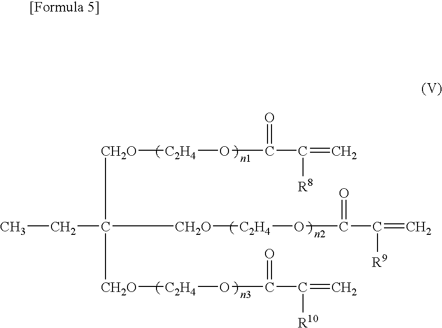
(in the formula, R⁸, R⁹ and R¹⁰ each represents a hydrogen atom or a methyl group and may be the same or different, and n1+n2+n3 is an integer of 1-20), 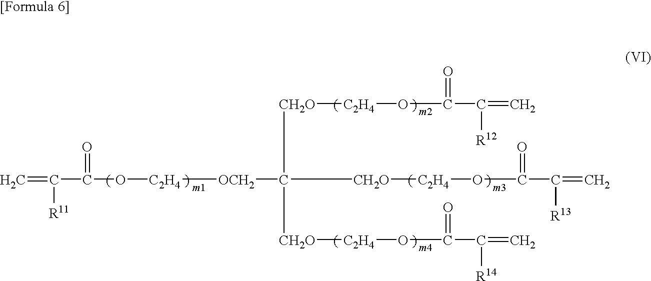
(in the formula, R¹¹, R¹², R¹³ and R¹⁴ each represents a hydrogen atom or a methyl group and may be the same or different, and m1+m2+m3+m4 is an integer of 1-20).

2. A photosensitive resin composition according to claim 1 which contains 0.01-30% by mass of an acridine compound represented by the following formula (VII) as the photopolymerization initiator (c): 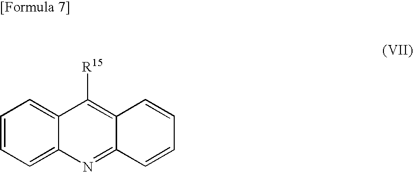
(in the formula, R¹⁵ represents a hydrogen atom, an alkyl group, an aryl group, a pyridyl group or an alkoxyl group).

3. A photosensitive resin composition according to claim 1 or 2 which contains 0.01-30% by mass of (e) an N-aryl-α-amino acid compound.

4. A photosensitive resin composition according to any one of claims 1-3 which contains 0.01-3% by mass of (f) a halogen compound.

5. A photosensitive resin laminate comprising a support and the photosensitive resin composition according to any one of claims 1-4 laminated on the support.

6. A method for forming a resist pattern on a substrate which includes a lamination step of forming a photosensitive resin layer using the photosensitive resin laminate according to claim 5 on a substrate, an exposing step, and a developing step.

7. A method for forming a resist pattern according to claim 6, wherein the exposure is carried out by direct drawing at the exposing step.

8. A method for producing a printed wiring board which includes a step of etching or plating the substrate on which a resist pattern is formed according to claim 6 or 7.

9. A method for producing a lead frame which includes a step of etching the substrate on which the resist pattern is formed by the method according to claim 6 or 7.

10. A method for producing a semiconductor package which includes a step of plating the substrate on which the resist pattern is formed by the method according to claim 6 or 7.

11. A method for producing a bump which includes a step of plating the substrate on which the resist pattern is formed by the method according to claim 6 or 7.

12. A method for producing a substrate having a rugged pattern which includes a step of working by sandblasting the substrate on which the resist pattern is formed by the method according to claim 6 or 7.
